(19) United States
(12) Patent Application Publication
(10) Pub. No.: US 2012/0031487 A1
(43) Pub. Date: Feb. 9, 2012

(54) Nanoscale High-Aspect-Ratio Metallic Structure and Method of Manufacturing Same

(75) Inventors: Ping Kuang, Troy, NY (US); Joong-Mok Park, Ames, IA (US); Wai Leung, Ames, IA (US); Kai-Ming Ho, Ames, IA (US); Kristen P. Constant, Ames, IA (US); Sumit Chaudhary, Ames, IA (US)

(73) Assignee: IOWA STATE UNIVERSITY RESEARCH FOUNDATION, INC., Ames, IA (US)

(21) Appl. No.: 13/274,383

(22) Filed: Oct. 17, 2011

Related U.S. Application Data
(63) Continuation-in-part of application No. 13/026,637, filed on Feb. 14, 2011.
(60) Provisional application No. 61/307,620, filed on Feb. 24, 2010.

(51) Int. Cl. H01L 31/0232; B05D 5/06; C23F 1/04; B32B 37/02; B32B 37/14; B05D 3/00; H01L 31/18; B05D 5/12; B82Y 99/00

(52) U.S. Cl. 136/256; 438/65; 174/250; 174/255; 427/162; 216/24; 427/58; 156/60; 257/E31.127; 977/932

(57) ABSTRACT

Nanoscale high-aspect-ratio metallic structures and methods are presented. Such structures may form transparent electrode to enhance the performance of solar cells and light-emitting diodes. These structures can be used as infrared control filters because they reflect high amounts of infrared radiation. A grating structure of polymeric bars affixed to a transparent substrate is used. The sides of the bars are coated with metal forming nanowires. Electrodes may be configured to couple to a subset of the rails forming interdigitated electrodes. Encapsulation is used to improve transparency and transparency at high angles. The structure may be inverted to facilitate fabrication of a solar cell or other device on the back-side of the structure. Multiple layered electrodes having an active layer sandwiched between two conductive layers may be used. Layered electro-active layers may be used to form a smart window where the structure is encapsulated between glass to modify the incoming light.

### CROSS-REFERENCE TO RELATED PATENT APPLICATIONS

This patent application is a Continuation-in-Part of co-pending U.S. patent application Ser. No. 13/026,637, filed Feb. 14, 2011, which claims the benefit of U.S. Provisional Patent Application No. 61/307,620, filed Feb. 24, 2010, the entire teachings and disclosure of which are incorporated herein by reference thereto.

### STATEMENT REGARDING FEDERALLY SPONSORED RESEARCH AND DEVELOPMENT

This invention was made in part with Government support under Grant Numbers DE-ACO2-07CH11358 awarded by the Department of Energy. The Government has certain rights in this invention.

### FIELD OF THE INVENTION

This invention generally relates to nanoscale high-aspect ratio metallic structures for use in solar cells and solid-state lighting devices, including organic light-emitting diodes.

### BACKGROUND OF THE INVENTION

Since the turn of this century, awareness of climate change, the search for clean energy, and the need for utilizing energy efficiently have been primary topics for both industry and academic research. Such interests have spurred developments in organic solar cells (OSCs) and organic light-emitting diodes (OLEDs). The advancements in organic solar cells and OLEDs are largely processing advantages including lower production costs, and simple fabrication methods when compared to their inorganic counterparts. Furthermore, OSCs and OLEDs offer the possibility of device fabrication on flexible substrates over large areas with higher throughput, which could greatly improve both their functionality and economy.

As a result of the above-mentioned developments, cost-effective solar-electric energy conversion is becoming increasingly important for the world. This is evidenced by the fact that direct solar-electric energy conversion using photovoltaic (solar cell) technology has grown exponentially over the last few years, as the costs of producing that energy have decreased from approximately $100/W in the late 1960's to the current level of approximately $3.50/W. This translates into electric energy generation costs of approximately 20-25 cents/kW hour (kWh). The current worldwide production of solar cells is approximately 3.4 gigawatts (GW)/year. This is equivalent to the power produced by almost four nuclear power plants in a single year. To compare, not a single nuclear plant has been ordered in the United States in the last thirty years.

Solar cell panel production has been growing at an annual growth rate of approximately 40%/year over the last ten years, and the current worldwide revenue from photovoltaic (PV) systems is about $17.8 billion/year. The solar cell industry raised nearly $10 billion dollars worldwide in 2007 to build their plants, with almost $5.3 billion dollars coming as equity contribution. As these numbers demonstrate, the solar cell industry is a major growth industry worldwide.

Indeed, the demand for solar cells to produce electric power is being driven both by market pull because of government subsidies (as in Germany) and by its improving economic competitiveness with conventional power, particularly where sun shines brightly and power costs are high, e.g., California. In California, entire new housing developments have solar cells built-in on their roofs, with the cells providing excess power during daytime which is sold to the grid, and with the grid providing nighttime power to the homes. The daytime tariffs for electricity consumption in California are very high (approximately 15-20 cents/kWh), because the peak power produced during daytime relies on very expensive natural gas, which is now costing upward of $10.00/MMBTU. Unfortunately, the costs of solar cell panels, after continuously reducing for approximately 20 years, have recently started to increase. One reason is due to the cost of the silicon wafers, which typically use a very expensive feedstock made of purified polysilicon. Polysilicon currently costs about $110-120/kg.

A typical solar-to-electric conversion efficiency for conventional silicon solar cells of approximately 15% means that a one square meter panel produces about 150 W. Silicon wafers used in solar cell panels are typically about 270-300 micrometers thick. Taking into account material lost during cutting and processing, silicon having a thickness of approximately a 600 micrometers is needed to make a conventional silicon solar cell. A 600-micrometer-thick silicon translates into 10 kg of silicon per kW of power produced, or at $120/kg, approximately $1,200/kW for the silicon alone. This is one reason the retail cost of the finished panel, which includes solar cells, encapsulation, front glass window, frame, etc., are now averaging about $4,800/kW. At these costs, electricity produced in sunny climates costs about 20-25 c/kWh, which is much too high to compete against power produced by conventional means, e.g., from coal. Therefore, the solar energy industry has been exploring a variety of ways to reduce the cost of the producing solar cells that make up the bulk of the cost of a typical solar panel.

Another factor contributing to the high cost of solar cells is the cost associated with the fabricating solar cell electrodes. Currently, most solar cells, and even most solid-state lighting (SSL) devices, employ indium tin oxide (ITO) coated substrates as their electrodes on the front side because of their relatively high transparency to visible light and low electrical sheet resistance. However, there is concern about the rising cost of ITO due to the limited supply of indium. Further, ITO electrodes can be relatively brittle with limited mechanical stability and limited chemical compatibility with active organic materials. Recently, there have been reports of investigations into carbon nanotube networks, random silver metal nanowire meshes, and patterned metal nanowire grids using nanoimprint lithography techniques in search of the replacement for ITO substrates. While the carbon nanotube networks and the silver metal nanowire meshes have equivalent optical transparencies as ITO substrates, their electrical conductivities are still inferior to the ITO substrates, and they suffer from current shunt due to the random nature of nanotube and nanowire networks.

The use of carbon nanotube networks and silver metal nanowire meshes as electrodes for organic solar cells and organic LEDs is described in a paper by Jung-Yong Lee, Stephen T. Connor, Yi Cui, and Peter Peumans, entitled “Solution-Processed Metal Nanowire Mesh Transparent Electrodes” published in The American Chemical Society publication, Nano Letters, Vol. 8, No. 2 pp. 689-692 (2008), the teachings and disclosure of which are incorporated in their entireties by reference thereto. The patterned metal nanowire grids show good visible transparency, however, the small line-width and thickness for the patterned metals lead to high sheet resistance as well as concerns about possible deterioration of the conductivity of the system with use. The use of patterned metal nanowire is described in a paper by L. Jay Guo and Myung-Gyu Kang entitled “Nanostructured Transparent Metal Electrodes for Organic Solar Cells” published by SPIE Newsroom, DOI: 10.1117/2.1200904.1364 (2009), the teachings and disclosure of which are incorporated in their entireties by reference thereto. Nanoimprinting of patterned metal nanowire grids for organic solar cells is described in a paper by Myung-Gyu Kang, Myung-Su Kim, Jinsang Kim, and L. Jay Guo entitled “Organic Solar Cells Using Nanoimprinted Transparent Metal Electrodes” published by Advanced Materials, DOI: 10.1002/adma.200800750 (2008), the teachings and disclosure of which are incorporated in their entireties by reference thereto. Nanoimprinting of patterned metal nanowire grids for organic LEDs is described in a paper by Myung-Gyu Kang and L. Jay Guo entitled “Nanoimprinted Semitransparent Metal Electrodes and Their Application in Organic Light-Emitting Diodes” published by Advanced Materials, DOI: 10.1002/adma.200700134 (2007), the teachings and disclosure of which are incorporated in their entireties by reference thereto.

It would therefore be desirable to have a solar cell electrode which has a relatively high transparency for light and a low electrical sheet resistance, the fabrication of which results in an electrode less expensive to manufacture than conventional ITO electrodes. Embodiments of the invention described herein provide such electrodes and such methods of fabrication. These and other advantages of the invention, as well as additional inventive features, will be apparent from the description provided herein.

### BRIEF SUMMARY OF THE INVENTION

In view of the above, embodiments of the present invention provide a new and improved solar cell electrode and method of fabricating solar cell electrodes that overcome one or more of the problems existing in the art. More specifically, embodiments of the present invention provide new and improved method utilizing nano-scale high-aspect-ratio metallic structures that can be used to enhance the performance of solar cells and LEDs and structures resulting therefrom. These nano-scale metallic structures may also be used as infrared control filters due to their ability to reflect a high amount of infrared radiation. In other embodiments, the nano-scale metallic structures may also include interdigitated conductors allowing realization of multiple potentials and use of switching signals for applications such as lateral photovoltaic cells.

In one aspect, embodiments of the invention provide a nanoscale electrode that includes a substrate transparent to visible light. An embodiment of the invention also includes a first metal rail spaced apart from, and parallel to, a second metal rail. In this embodiment, the two metal rails are supported by, and affixed to, a polymer bar disposed entirely between the first and second metal rails. Further, in an embodiment of the invention, the polymer bar is attached to the substrate.

In another aspect, embodiments of the invention provide a method of fabricating a nanoscale electrode that includes the steps of forming a material into a bar, and affixing the material to a transparent substrate. In an embodiment of the invention, the method also includes depositing a metal coating over the exposed side and top portions of the material, and removing the metal coating from a top portion of the material. In another embodiment, the method includes applying a grating mask on one end of the bars, depositing the metal coating in a first direction, applying a grating mask on the other end of the bars, and depositing the metal coating in a second direction. Thereafter the metal coating from a top portion of the material is removed resulting in interdigitated electrodes.

In accordance with an embodiment described herein, a method of manufacturing a nanoscale electrode includes the steps of filling a plurality of grooves of an elastomeric mold with a first polymer that can be UV cured. Each groove in the plurality of grooves in are parallel with each other. The first polymer is partially cured, and a second polymer is then coated on the first polymer, resulting in a filled elastomeric mold. The first and second polymers are suitable polymers of appropriate viscosity and with physical and chemical properties that allow the building of a layered structure and cured via UV light exposure. A transparent substrate is placed on the filled elastomeric mold, and the filled elastomeric mold and substrate are exposed to UV light. The filled elastomeric mold is peeled away from the first polymer and the second polymer such that the first polymer and second polymer form a polymer layer of polymer bars on the substrate.

The plurality of bars are then metal coated by oblique angle deposition. This is done to address the unique need for transparency that is met by using an oblique angle deposition method. Specifically, to maintain transparency, the substrate between the bars cannot have metal deposited thereon. As such, the oblique angle deposition method allows only the sides and the top of the bars to be coated, while leaving the substrate between the bars free of metal. In at least one embodiment, the metal coating on the top of the bars or bars is then removed by argon ion milling of the metal coating off of the top of the bars. In an alternate embodiment of the invention, the metal on top of the bars is removed by reactive ion etching.

In one embodiment, the metal deposition is performed such that metal film is also deposited on the substrate around the outside edges of the bars to electrically connect the vertical metal coatings on the sides of the bars to form a single potential electrode. In another embodiment, a mask is used to prevent metal from being deposited on one end of the bars and that end of the substrate during a first deposition, and to prevent metal from being deposited on an opposite end of the bars and substrate during a second deposition such that electrical connection between alternate vertical metal coatings on the sides of the bars are electrically isolated from one another to form a multiple-potential electrode with interdigitated electrode fingers.

In another embodiment, encapsulation is used with the structures to improve optical transparency and transparency at high angles. In such an embodiment, once the base structure is completed, a drop of polyeutherane (PU) liquid prepolymer is placed on top of the etched structure and UV cured, and a second glass substrate is placed on top to encapsulate the entire structure. The additional PU fills in the air channels bewteen the metal sidewalls and also forms a layer over the entire structure to reduce the diffraction effect from the grating pattern. Such a technique is particularly applicable to large area samples (2 in×2 in, or bigger, 6 in ×6 in, etc.).

In yet another embodiment, an inverted structure is utilized to facilitate fabrication of a solar cell or other device on the back-side of the completed structure. In this embodiment, the PU grating is fabricated on a water-soluble sacrificial layer coated glass substrate. After metal deposition and argon ion milling, a small droplet of PU prepolymer is placed on the sample to fill in the trenches of the grating structure. The PU prepolymer also serves to glue a second glass substrate onto the sample. After the PU filling is ultraviolet cured and solidified, the structure is submerged in distilled water to dissolve the sacrificial layer, and the original glass substrate is detached. Upon the separation of the original glass substrate, the bottom part of the structure is exposed and the structure is inverted with respect to the original structure. The active materials of a solar cell and the other electrode can be fabricated on this transparent electrode substrate.

In a further embodiment, a sandwich structure, i.e. multiple layered electrodes, are formed such that an active layer is sandwiched between two conductive layers. Once the PU grating is fabricated, metal angle-deposition is used to coat the top and one sidewall of the PU grating. Then, a dielectric layer, such as silicon dioxide, is also deposited onto the metal layer from the same side and deposition angle. A second layer of metal (same material as the first metal, or different metal) is angle deposited onto the dielectric layer. Lastly, the low angle argon ion milling is performed to remove all three layers on top of the PU grating, leaving a sandwiched (metal/dielectric/metal) structure on one sidewall of the PU grating pattern.

In yet a further embodiment, a structure with layered electro-active layer for use as a smart window (where the structure is encapsulated between glass to modify the incoming light is formed. Once the PU grating is fabricated, metal angle deposition is performed for one side. Then a second metal is angle deposited from the other side. The top metal layers are removed by low angle argon ion milling or other process. Lastly, an electrically responsive material is filled into the channels of the structure. This structure can be sandwiched between panes of glass for use as a ‘smart window’.

In further embodiments of the present invention, both quasi-2D and actual 2D structures are formed.

Other aspects, objectives and advantages of the invention will become more apparent from the following detailed description when taken in conjunction with the accompanying drawings.

### BRIEF DESCRIPTION OF THE DRAWINGS

The accompanying drawings incorporated in and forming a part of the specification illustrate several aspects of the present invention and, together with the description, serve to explain the principles of the invention. In the drawings:

FIGS. 1A-1F are schematic diagrams that illustrate the steps of a two-polymer microtransfer molding process, according to an embodiment of the invention;

FIG. 2 is a is a schematic diagram showing the angle deposition of metals on a one-layer polyurethane grating, according to an embodiment of the invention;

FIGS. 3A and 3B are schematic diagrams illustrating the argon ion milling of metals on a one-layer polyurethane grating, according to an embodiment of the invention;

FIG. 4 is a pictorial illustration of exemplary electrodes constructed in accordance with an embodiment of the invention;

FIG. 5 is a graphical representation of the percentage of light transmitted to the solar cell by wavelength for an exemplary electrode constructed in accordance with an embodiment of the invention;

FIGS. 6A-E are simplified illustrations of the multi-step angle deposition process of metals on a one-layer polyurethane grating and a top view illustration of a resulting electrode structure, according to an embodiment of the invention;

FIGS. 7A-B are simplified illustrations of the multi-step angle deposition process of metals on a one-layer polyurethane grating resulting in interdigitated electrodes, according to an alternate embodiment of the invention;

FIG. 8 is a is a pictorial illustration of exemplary interdigitated electrodes constructed in accordance with an embodiment of the invention;

FIGS. 9A-D are simplified illustrations of the encapsulation of the one-layer polyurethane grating to improve optical transparency in accordance with an embodiment of the present invention;

FIGS. 10A-D are simplified illustrations of an inversion of the one-layer polyurethane grating to allow fabrication of a solar cell on a transparent electrode in accordance with an embodiment of the present invention;

FIGS. 11A-D are simplified illustrations of the fabrication process to produce a sandwiched metal/dielectric/metal structure on the one-layer polyurethane grating in accordance with an embodiment of the present invention;

FIGS. 12A-D are simplified illustrations of the fabrication process to produce a structure with active layer filling on the one-layer polyurethane grating to enable use as a smart window in accordance with an embodiment of the present invention;

FIG. 13 is a schematic illustration of a smart window constructed in accordance with the process of FIGS. 12A-D;

FIG. 14 is a schematic illustration of a quasi-2D structure in accordance with an embodiment of the present invention;

FIG. 15 is a top view schematic illustration of a 2D structure in accordance with an embodiment of the present invention;

FIG. 16 is a perspective view schematic illustration of the 2D structure of FIG. 15;

FIG. 17 is a SEM image of an embodiment of a PU one-layer grating having a lower aspect ratio structure; and

FIG. 18 is a schematic illustration of an embodiment of the lower angle metal deposition used to construct a lower aspect ratio structure having metal sidewalls.

While the invention will be described in connection with certain preferred embodiments, there is no intent to limit it to those embodiments. On the contrary, the intent is to cover all alternatives, modifications and equivalents as included within the spirit and scope of the invention as defined by the appended claims.

### DETAILED DESCRIPTION OF THE INVENTION

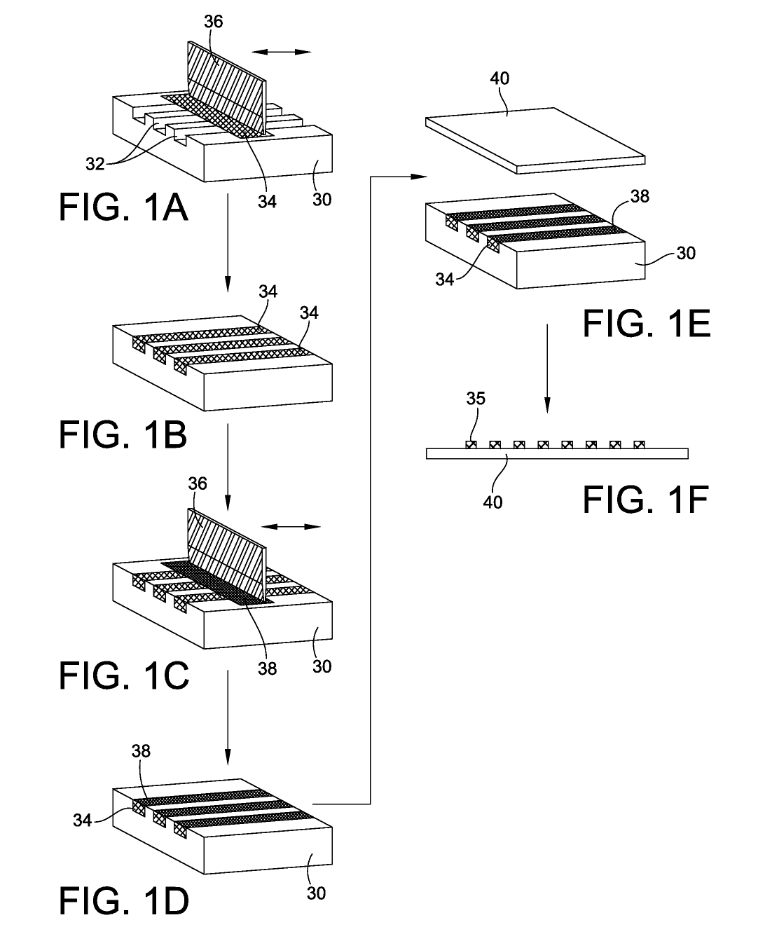

FIGS. 1A-1F are schematic diagrams that illustrate the steps of a two-polymer microtransfer molding (2-P μTM) process used in manufacturing an embodiment of the invention. Such a two-polymer microtransfer molding process is described in U.S. Pat. No. 7,625,515, entitled Fabrication of Layer-By-Layer Photonic Crystals Using Two Polymer Microtransfer Molding, to Lee et al., and assigned to the assignee of the instant application, the teachings and disclosure of which are hereby incorporated in their entireties herein by reference thereto. In at least one embodiment, the nanoscale metallic structures described herein are configured to provide plasmonic light concentration to enhance light absorption in solar cells, while also reflecting high amounts of infrared radiation.

As shown in FIGS. 1A-F, the photonic structure is prepared in a multiple stage process. PDMS (polydimethylsiloxane) or other suitable elastomeric molds 30 cast from a master pattern out of a photoresist relief pattern on a silicon wafer are used in the manufacture of the photonic structures. Typically, the PDMS mold is created from a master pattern that usually only has parallel lines. However, it should be recognized that any pattern may be used for the master pattern. In one embodiment, the master pattern is made by spinning on a layer of photoresist on a silicon wafer. In some embodiments of the invention, photolithography or e-beam lithography is used to generate a multiple line pattern on the resist-covered wafer and the resist is developed, resulting in the master pattern. In an alternate embodiment, two-beam laser holography is used to is used to generate a multiple line pattern on the resist-covered wafer. The PDMS mold is obtained by pouring PDMS on the master pattern. After the elastomeric mold 30 is cured, it is peeled off of the master pattern, resulting in an elastomeric mold 30 having channels 32 reflecting the structure of the master pattern.

A drop of a first prepolymer 34, such as polyurethane (PU), is placed just outside of a patterned area on a PDMS mold and dragged at a constant speed across the PDMS mold 30 with a blade 36 (see FIG. 1A). The blade 36 is not in contact with the PDMS mold 30. In one embodiment, the blade 36 is a metal blade controlled by mechanical actuators. After dragging through the patterned area, the prepolymer 34 only fills in the channels without any residue (see FIG. 1B). This filling method is referred to as “wet-and-drag” (WAD). In one embodiment, the speed for a forward movement (i.e. wetting) is around 0.5 mm/sec. The speed for a backward movement (i.e., dewetting) is around 30 μm/sec to achieve flat meniscus of the prepolymer 34 after filling while minimizing swelling of the PDMS mode by the prepolymer 34. Other speeds may be used.

The filled prepolymer 34 is partially cured for approximately four minutes so it solidifies. In one embodiment, an ultraviolet (UV) dose for the partial curing of prepolymer 34 is within the range of 0.45 to 2.7 J/cm². Then, a second WAD is performed to apply a second prepolymer 38, such as polymethacrylate, which only wets the top surface of the polyurethane prepolymer 34 but not the PDMS mold 30 (see FIG. 1C), resulting in a filled PDMS mold 30 (see FIG. 1D). In one embodiment, the speed for a forward movement is around 0.5 mm/sec. The speed for a backward movement is around 100 μm/sec to minimize swelling of the PDMS mold 30 by the prepolymer 38. Other speeds may be used.

By placing a substrate 40 on the mold 30 (see FIG. 1E) and exposing them to UV light for approximately three hours, the filled microstructure grating of polymer bars 35 formed from prepolymer 34 and prepolymer 38 adheres to the substrate 40. In at least one embodiment, the substrate 40 is a transparent material such as glass or sapphire. The PDMS mold 30 is then peeled away leaving a single-layer polyurethane grating structure of the polymer bars 35 on the substrate 40 (see FIG. 1F).

In an embodiment of the invention, therefore, the polymer grating structure shown in FIG. 1F is fabricated by the two-polymer microtransfer molding technique to form the micron or submicron scale gratings of bars 35. For the fabrication, the visibly transparent substrate 40, e.g. glass or sapphire, is cleaned ultrasonically in distilled water so that it is without dust and residue on the surface. In this two-polymer microtransfer molding process discussed above, two pre-polymers 34, 38 are used, one as the filler, and the other as the adhesive to enhance the bonding strength between the first layer and the substrate. In at least one embodiment, the filler is UV-curable polyurethane and the adhesive is polymethacrylate.

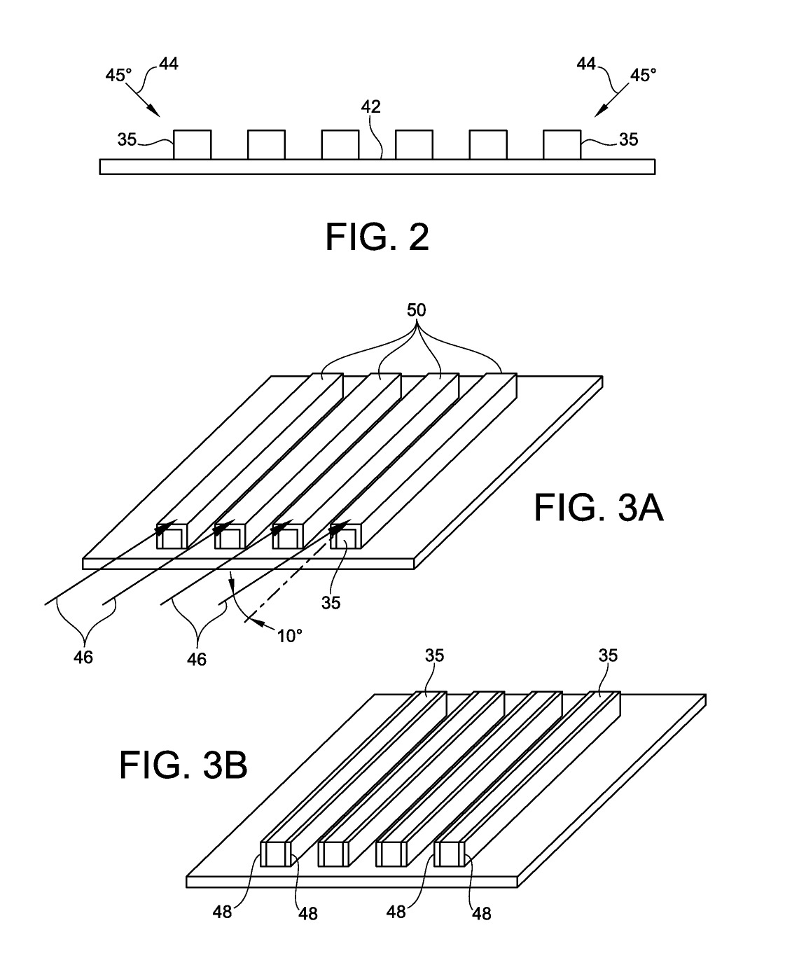

After the polyurethane gratings of bars 35 are fabricated, in one embodiment a thin layer of metal (e.g., 80-100 nanometers), such as gold, silver, copper, etc., is angle deposited onto the polyurethane bars 35 by thermal evaporation, as shown in the simplified schematic diagram of FIG. 2. Since metal deposition at the normal incidence not only coats the polyurethane bars 35 but also the exposed substrate surface 42 in between each polyurethane bar 35, a stationary sample holder with a tilted angle, e.g., at 45 degrees (shown by arrows 44), is used so that the metal is only deposited on the sidewalls and the top of polyurethane bars 35. To coat both sides of the polyurethane bars 35, two separate angle depositions of metal film are done (each of arrows 44) to cover the side walls and the top surface of the bars 35. The angle at which the deposition is done is determined by the gap between two adjacent bars 35 and the height of each of the bars 35 for the grating. In the case where the bar gap is same as the bar height as shown in FIG. 2, a 45 degree angle of deposition is used. For other dimensions, the angle can be adjusted accordingly such that only the sides and top of the bars 35 are coated, but not the substrate surface 42 between the bars 35. Depositing the metal in this manner is advantageous because the space between each polyurethane bar 35 is not covered by metal and therefore remains transparent, enhancing the optical transmission of the overall structure.

In an embodiment of the invention, the optical transparency of the structure may be improved further when the metal layer on top 50 of the polyurethane bars 35 is removed by, e.g., argon ion milling. In an alternate embodiment of the invention, the metal layer on top 50 of the polyurethane bars 35 may be removed by reactive ion etching. In yet another embodiment of the invention, the metal layer on top 50 of the polyurethane bars 35 may be removed by argon plasma sputtering.

Turning specifically to FIG. 3A there is illustrated a schematic diagram of the argon ion milling of metal from the top 50 of the one-layer polyurethane grating, in accordance with an embodiment of the invention. In one embodiment the parameters for the argon ion milling power are 3 kV and 1 mA. In this process, the sample is positioned with the ion gun beam direction being aligned parallel to the direction of the grating so that the metal on the sides of the bars 35 is not affected by the argon ions. The ion beam is positioned at a low incoming angle, e.g., at 10 degrees (shown by arrows 46), so the ion beam etches the metal from the top 50 surface at a controllable rate, and so that the ion beam impacts a larger surface area.

In at least one embodiment, after the ion milling (or reactive ion etching, or argon plasma sputtering) has removed the top metal layer from the bars 35, the metal on the sidewalls of the bars 35 is left intact to form metal rails 48 as shown in FIG. 3B. The polyurethane bars 35 may be partially etched by the argon ions as well, but this does not affect the optical transparency of the resultant structure. In at least one embodiment, after removal of the metal layer on top of the polyurethane bars 35, oxygen plasma etching or reactive ion etching is used to remove a portion of the exposed polyurethane bar 35 to improve light transmission through the polyurethane and to reduce absorption of UV by the polyurethane.

As may be seen in this FIG. 3B, a plurality of parallel structures, each including a pair of parallel metal rails 48 separated by and affixed to a polyurethane bar 35 is formed by the process discussed above. In one embodiment of the invention, the plurality of parallel structures are spaced evenly, that is, at a fixed distance from adjacent parallel structures. The spacing between these parallel structures in certain embodiments may range from 0.75 micrometers to 3 micrometers.

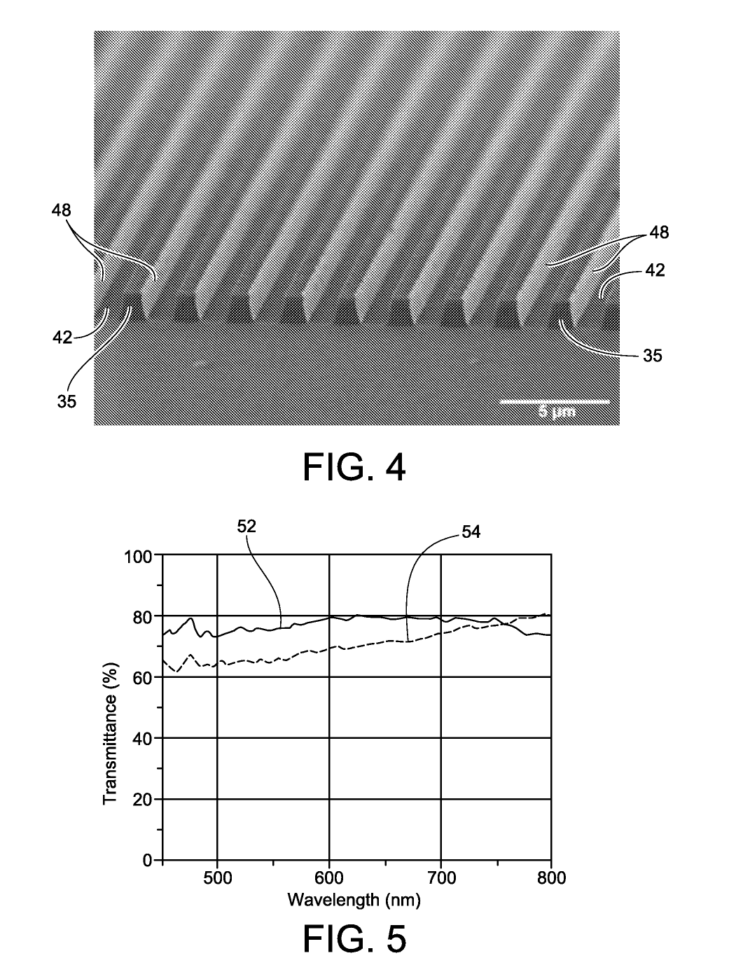

FIG. 4 illustrates an exemplary embodiment of a nanoscale high-aspect-ratio metallic electrode constructed in accordance with the teachings of the present invention. The polyurethane grating structure in such an embodiment may have at least two different periodicities, 2.5 micrometers and 1 micrometer. In the specific embodiment of FIG. 4, the polyurethane bars 35 have a trapezoidal cross-section, wherein this trapezoidal shape replicates the master used in the fabrication process. In an embodiment having the 2.5-micrometer-periodicity structure, the polyurethane bar 35 height from the substrate surface 40 is approximately 1.25 micrometers, and the top and bottom widths are 0.85 micrometer and 1.35 micrometers, respectively. In the illustrated embodiment, the base angle for this 2.5-micrometer version of the polyurethane bars 35 is about 12 degrees. In an embodiment having 1-micrometer-periodicity gratings, the polyurethane bar 35 height from the substrate surface 42 is approximately 570 nm, and the top and bottom widths are 330 nm and 580 nm, respectively. In such an embodiment, the base angle for this 1-micrometer version of the polyurethane bars 35 is about 15 degrees.

In each of these exemplary embodiments, the metal rails 48 formed from a metal such as gold, silver, copper, etc., have heights estimated to be the same as that of PU bars 35 (approximately 1.2 μm). The thickness of the metal rail 48 formed as discussed above is approximately 70 nm. As such, the metal rails 48 are effectively nanowires with a high 17:1 aspect ratio. Since a metal such as gold was deposited on both sidewalls of the bars 35, the periodicities of the gold nanowire patterns (metal rails 48) are reduced by half to around 1.2-1.3 μm.

FIG. 5 is a graphical representation of the percentage of light transmitted to a solar cell by wavelength for an exemplary electrode constructed in accordance with an embodiment of the invention. The range of wavelengths along the x-axis of the graph corresponds to wavelengths for visible light. The graph shows the percentage of light transmission for polyurethane bars 35 (see FIG. 4) spaced at 2.5 micrometers having with 100 nm-thick gold rails 48 shown by trace 52 or 100 nm-thick copper rails 48 shown by trace 54 on a glass substrate 40. As can be seen from the graph, the percentage of light transmitted through the polyurethane grating is always greater than 60%, but transmission rates approaching 80% are also achievable.

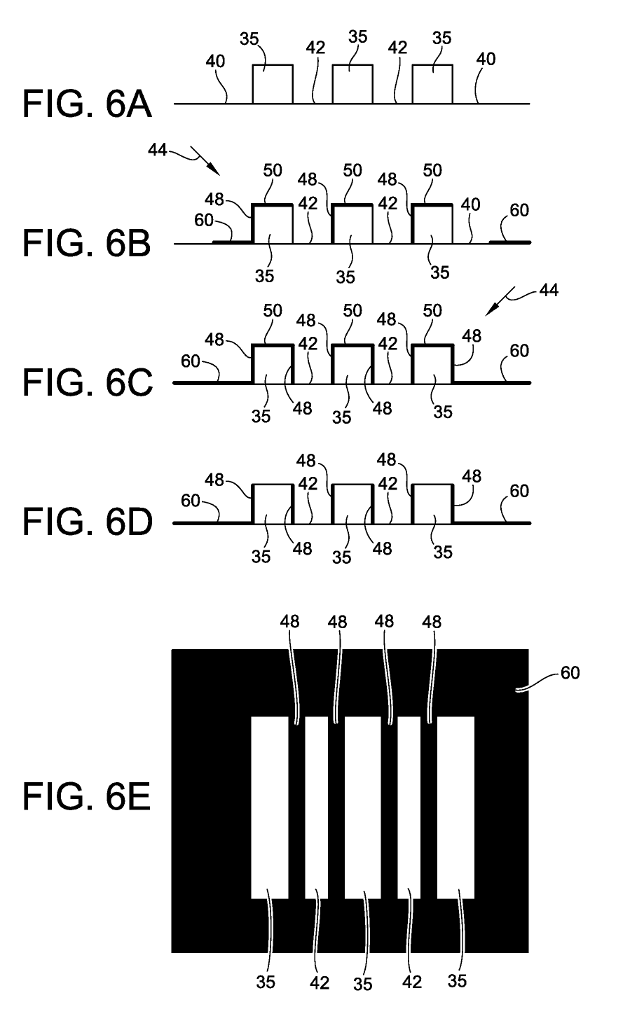

When using the metal deposition method discussed above, a metal film 60 may also be deposited on the substrate 40 outside of or around the grating structure of the bars 35. This may be seen from an inspection of FIGS. 6A-E, which illustrate the metal deposition process illustrated briefly in FIG. 2 in a step-by-step fashion, including a top view illustration of the resulting structure in FIG. 6E (scale exaggerated to allow better understanding).

As shown in FIG. 6A, the grating structure of bars 35 on a substrate 40 ready for metal deposition is shown in an end view. FIG. 6B illustrates the angled deposition (arrow 44) of metal on the grating structure. In this first angled deposition, metal 60 is deposited on a leading portion of the substrate 40 before the first bar 35 (the left side of FIG. 6B), on one side of bars 35, on the top 50 of the bars 35, and beyond the last bar 35 of the grating (shown by metal 60 on the right side of FIG. 6B). Due to the angled deposition (arrow 44), no metal is deposited on the substrate surface 42 between the bars 35.

As shown in FIG. 6C, the second angled deposition (arrow 44) of metal on the grating structure is performed. In this second angled deposition, metal 60 is deposited on a leading portion (right side of FIG. 6C) of the substrate 40 before the first bar 35 (viewed from arrow 44), on the other side of bars 35, again on the top 50 of the bars 35, and beyond the last bar 35 of the grating (shown by metal 60 on the left side of FIG. 6C). Due to the angled deposition (arrow 44), no metal is deposited on the substrate surface 42 between the bars 35 during this second deposition step.

FIG. 6D shows the grating structure after the step of ion milling or etching has taken place to remove the metal from the top 50 (see FIGS. 6B-C) of the bars 35. As discussed above, this operation leaves the metal rails 48 attached to the sides of the bars 35. It also leaves the metal 60 on the substrate 40 around the bars 35. As shown from the top view illustration of FIG. 6E, in embodiments wherein the bars 35 do not extend to the edge of the substrate, the metal deposition steps of FIGS. 6B-C also deposits metal 60 on the substrate at either end of the bars 35.

In the embodiment shown in FIG. 6E, the substrate extends beyond the bars 35 on all sides and is coated with metal 60. In such an embodiment, this metal 60 may serve as an electrical connection point when the structure is used as an electrode. This is possible because there is no electrical isolation between the vertical metal rails 48 deposited on each side of each of the PU bars 35. In other words, in the illustrated embodiment the metal 60 is electrically coupled to each metal rail 48.

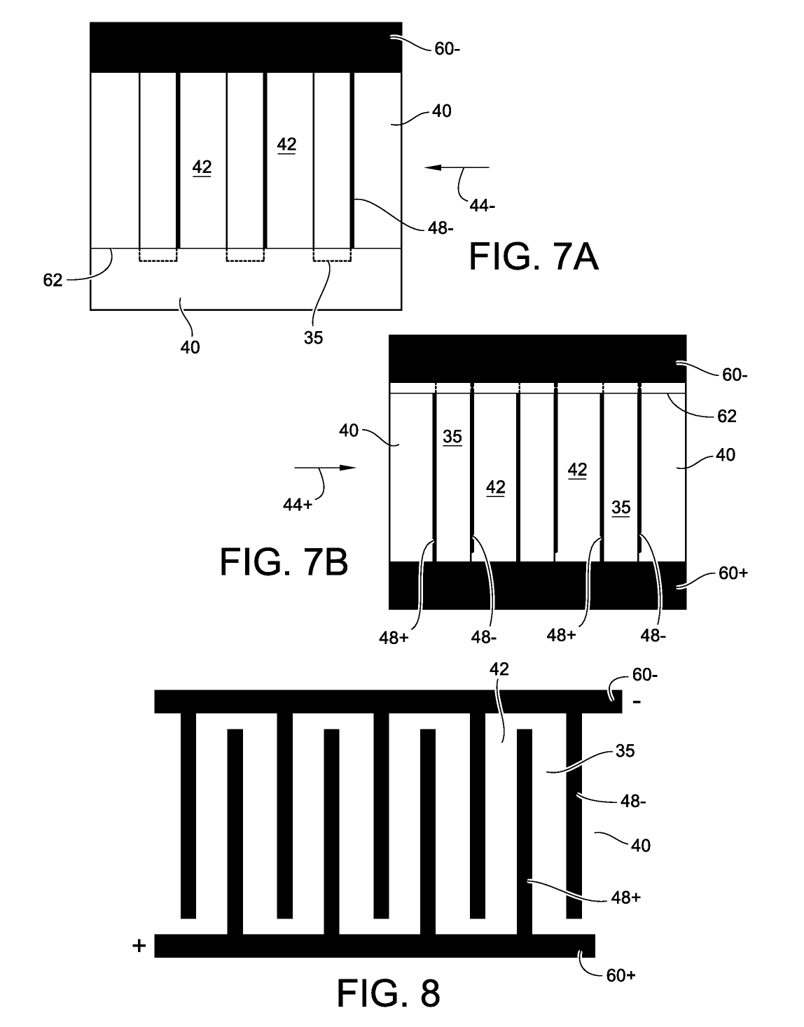

However, in an alternate embodiment of the present invention, a modified deposition scheme such as that illustrated in FIGS. 7A-B, can provide electrical isolation between the two alternate vertical metal rails 48 on each bar 35. As with the above described embodiment, a 1-D grating on a substrate 40 provides the basic structure. During the first angle deposition (arrow 44⁻) shown in FIG. 7A, the lower part of the edge of the bars 35 and the substrate 40 are covered by a mask 62. During this first deposition, the right side wall of the bars 35 not covered by the mask 62 are covered with the metal film 48⁻ as is the unmasked portion of the substrate 60⁻ beyond the top end of the bars 35 as oriented in FIG. 7A. It is noted that the metal film on top of the grating is not shown to better illustrate the side wall structure (the top film is removed after all the depositions as discuss above).

The second angle deposition (arrow 44⁺) is performed with the top edge of the grating structure and the substrate previously coated with metal 60⁻ covered by a mask 62 as shown in FIG. 7B. During this second deposition, the left side wall of the bars 35 not covered by the mask 62 are covered with the metal film 48⁺ as is the unmasked portion of the substrate 60⁺ beyond the lower end of the bars 35 as oriented in FIG. 7B. It is noted that the metal film on top of the grating is not shown to better illustrate the side wall structure (the top film is removed after all the depositions as discuss above).

After removing the top metal film with ion milling or etching, the resulting structure will look like that shown in FIG. 8. As may be seen, there is no electrical connection between the metal rails 48⁻, 48⁺ on either side of each bar 35. However, there is an electrical connection through the metal 60⁻, 60⁺ on the top and bottom on the substrate 40 (as oriented in FIG. 8) to each metal rail 48⁻, 48⁺, respectively. This allows the metal 60⁻, 60⁺ to be used as electrodes for separate electrical connection. The alternate fingers formed by rails 48⁻, 48⁺ are isolated from each other and can be used as interdigitated electrodes for appropriate applications.

In one embodiment, the volume (42) between the interdigitated electrodes (48⁻, 48⁺) is filled with a material responsive to an applied field. In such an embodiment, the structure can be switched at will via a bias applied to the material within the structure by the interdigitated electrodes (48⁻, 48⁺). Such electrically active materials include liquid crystals phases, which can include a number of different morphologies and can be low melting inorganic phases or aromatic organics such as para-Azoxyanisole (PAA). In addition to liquid crystals, piezoelectric materials, photovoltaic materials, photo-luminescent materials, and organic (and inorganic) light emitting materials may also be used in further embodiments. Also, nonlinear materials could be used in other embodiments, but they are not always necessary for interdigitating.

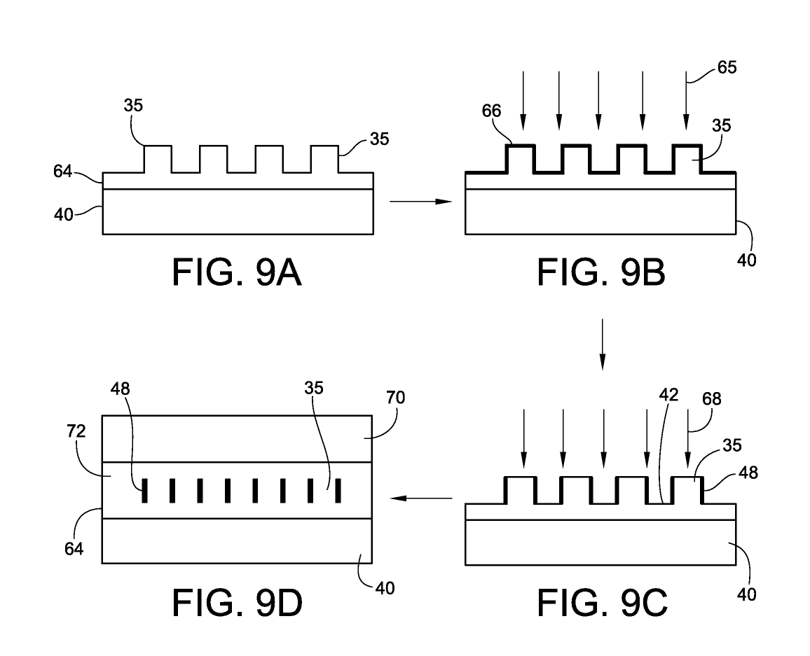

Turning now to FIGS. 9A-D, there are illustrated process steps that provide an encapsulation of the one-layer polyurethane grating to improve its optical transparency and its transparency at high angles, e.g. >50°. Specifically, a PU grating of polyeurthane bars 35 is made by placing excess PU liquid prepolymer on a glass substrate 40. Using a PDMS mold 30 (see FIG. 1) with grating patterns or channels 32, a direct stamping process is performed to transfer the pattern to the PU. After UV curing the PU is solidified, and the PDMS mold is removed. Because this process uses excess PU liquid prepolymer, there is an underlayer 64 of PU between the PU grating pattern (bars 35) and the glass substrate 40 as shown in FIG. 9A.

Next, as shown in FIG. 9B, a conformal coating 66 of metal is carried out by a sputtering process as illustrated by arrows 65. As shown in FIG. 9C, argon plasma etching illustrated by arrows 68 is performed to remove the metal on the top of PU bars 35 as well and in the channels of exposed substrate surface 42 in between each polyurethane bar 35. The etching process is highly anisotropic so the metal sidewalls forming the vertical metal rails 48 are intact. Finally, as illustrated in FIG. 9D, a drop of PU liquid prepolymer 72 is placed on top of the etched structure of FIG. 9C and UV cured, and a second glass substrate 70 is placed on top to encapsulate the entire structure. The additional PU liquid prepolymer 72 fills in the air channels between the metal sidewalls forming the vertical metal rails 48 and also forms a layer over the entire structure to reduce the diffraction effect from the grating pattern.

This technique is particularly well suited for application to large area samples (2 in ×2 in, or bigger, 6 in ×6 in, etc.) though it can also be used for smaller areas as well. The 2P-μTM technique of FIG. 1 may also be used for large area samples (without PU underlayer 64), although the process would be slightly modified. Different periodicities and height of PU bars 35 can be made with both techniques.

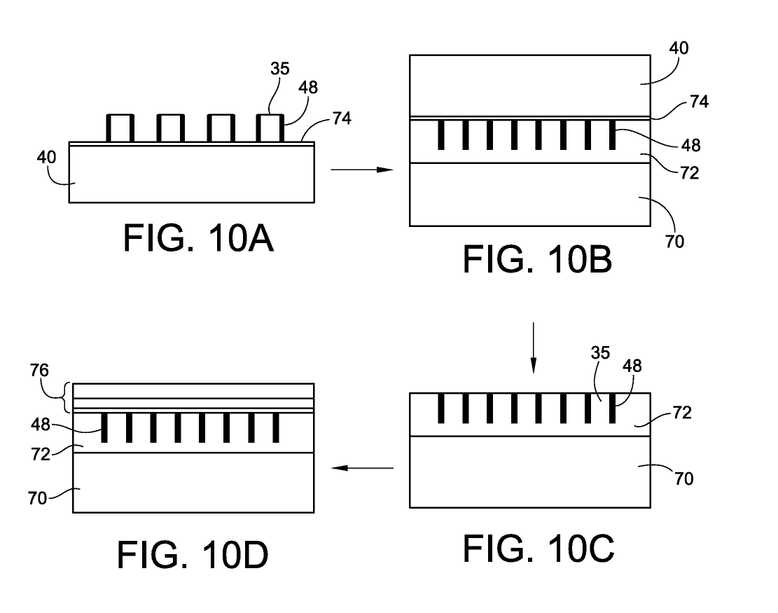

Turning now to FIGS. 10A-D, there are illustrated simplified process diagrams for constructing an inverted structure to facilitate fabrication of a solar cell or other device on the back-side of the one-layer polyurethane grating structure. Specifically, as illustrated in FIG. 10A, the PU grating of bars 35 is fabricated on a water-soluble sacrificial layer 74 coated glass substrate 40. After metal deposition and argon ion milling as described above, a small droplet of PU prepolymer 72 is placed on the sample to fill in the trenches of the grating structure between the polyurethane bars 35 and the vertical metal rails 48 as shown in FIG. 10B. The PU prepolymer 72 also serves to glue a second glass substrate 70 onto the sample.

After the PU prepolymer 72 filling is ultraviolet cured and solidified, the sample is submerged in distilled water to dissolve the sacrificial layer 74, and the original glass substrate 40 is detached as shown in FIG. 10C. Upon the separation of the original glass substrate 40, the bottom part of the structure is exposed and the sample is inverted with respect to the original structure. As shown in FIG. 10D, the active materials of a solar cell and the other electrode (collectively illustrated as 76) can then be fabricated on this transparent electrode substrate.

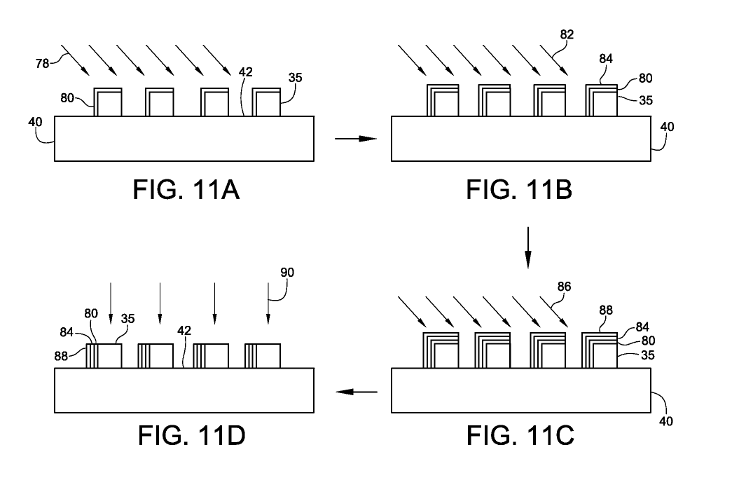

Turning now to FIGS. 11A-D, there are illustrated a method to fabricate a sandwich structure of multiple layered electrodes where an active layer is sandwiched between two conductive layers (metal/dielectric/metal structure) on the one-layer polyurethane grating in accordance with an embodiment of the present invention. Specifically, as illustrated in FIG. 11A, metal angle-deposition represented by arrows 78 is used to coat the top and one sidewall of the PU grating polyurethane bars 35 with a first metal layer 80. Then, as shown in FIG. 11B, a dielectric layer 84, such as silicon dioxide, is also angle deposited as illustrated by arrows 82 onto the metal layer 80 from the same side and deposition angle. As illustrated in FIG. 11C, a second layer 88 of metal (same material as the first metal layer 80, or a different metal) is angle deposited as shown by arrows 86 onto the dielectric layer 84. As shown in FIG. 11D, the low angle argon ion milling illustrated by arrows 90 is performed to remove all three layers 80, 84, 88 on top of the PU grating bars 35, leaving a sandwiched (metal/dielectric/metal) structure on one sidewall of the PU grating pattern bars 35.

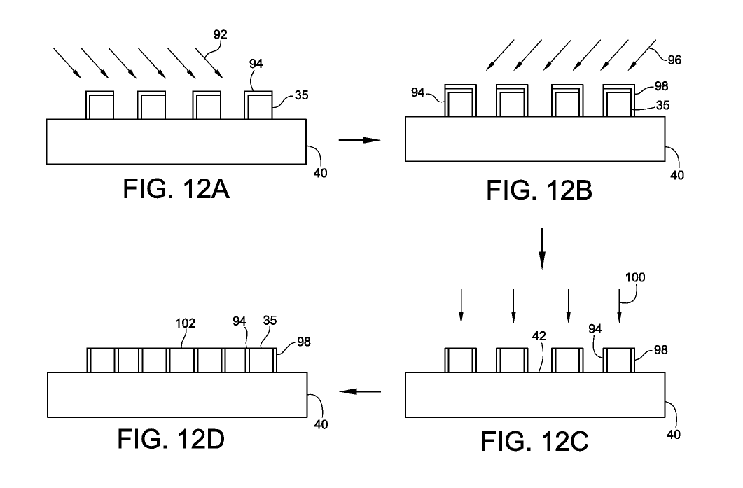

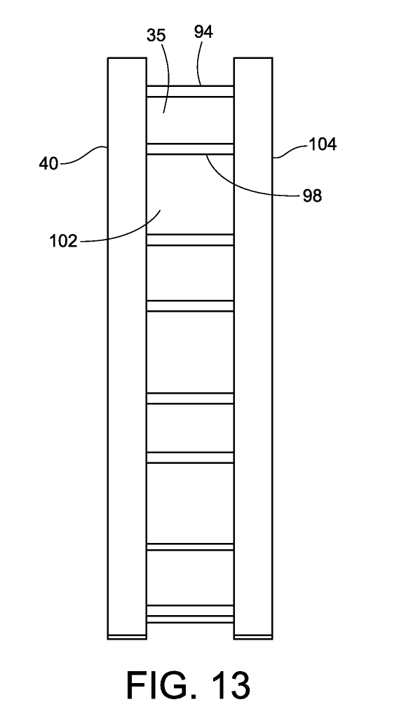

FIGS. 12A-D illustrate the fabrication process to produce a structure with active layer filling on the one-layer polyurethane grating to enable use as a smart window in accordance with an embodiment of the present invention. First, as shown in FIG. 12A metal angle deposition illustrated by arrows 92 is performed to deposit a first metal layer 94 on one side of the PU bars 35. Second, as shown in FIG. 12B a second metal layer 98 is angle deposited as illustrated by arrows 96 from the other side of the PU bars 35. FIG. 12C illustrates that the two metal layers deposited on the top of bars 35 are removed by low angle argon ion milling shown by arrows 100 or other process. As shown in FIG. 12D, an electrically responsive material 102 (such as that discussed above with regard to FIG. 8) is filled into the channels of the structure between bars 35. As shown in FIG. 13, this structure can be sandwiched between panes of glass 40, 104 for use as a smart window to modify the incoming light.

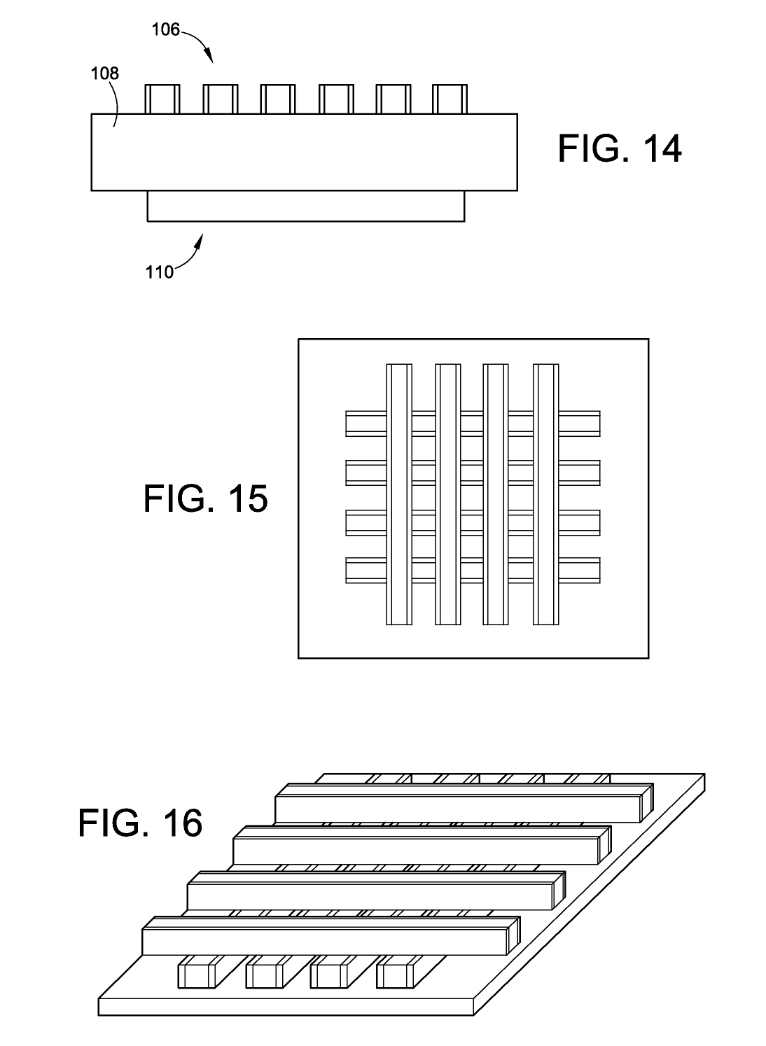

To realize high IR reflection in both polarizations, the quasi-2D structure of FIG. 14 was constructed. As may be seen, this quasi-2D structure is fabricated by including a 1D grating structure 106, 110 on each of two sides of a substrate 108. Because glass substrates have some absorption in the mid-IR range, a 400 μm sapphire is used in a preferred embodiment as the substrate 108. In this structure, two one-layer PU grating structures 106, 110 were fabricated on both sides of the substrate 108, with the one-layer PU grating structures 106, 110 aligned orthogonally to each other at around 90°.

In one embodiment, the periodicity is approximately 2.5 μm, the width is approximately 1.2 μm, and the height is approximately 1.2 μm. Silver was deposited using the angle evaporation technique to coat the sidewalls as well as the top of the PU bars, and the metal on the PU top surface is removed by the argon ion milling as discussed above.

When a white light source was passed through the structure of FIG. 14, the transmitted light forms a 2D diffraction pattern. The average reflection intensity of both polarizations is about 80%, which shows that this quasi-2D structure is suitable to be used as hot mirrors in IR reflecting applications.

In another embodiment of a layer by layer (LBL) structure that provides high IR reflection in both polarizations, as illustrated in FIGS. 15 and 16, an actual 2D structure (rather than the quasi-2D structure of FIG. 14) is shown. In one embodiment, the structure of FIGS. 15 and 16 is fabricated with a different method using a top-down process such as reactive ion etching (RIE) to remove the metal on the PU top surface without removing the PU. This 2D structure has high reflection in the infrared range in both polarizations, and is a very good spectral reflector in at least the mid-IR range. In another embodiment, the periodicity is reduced to approximately 1 μm in order to use such structure for near-IR reflection.

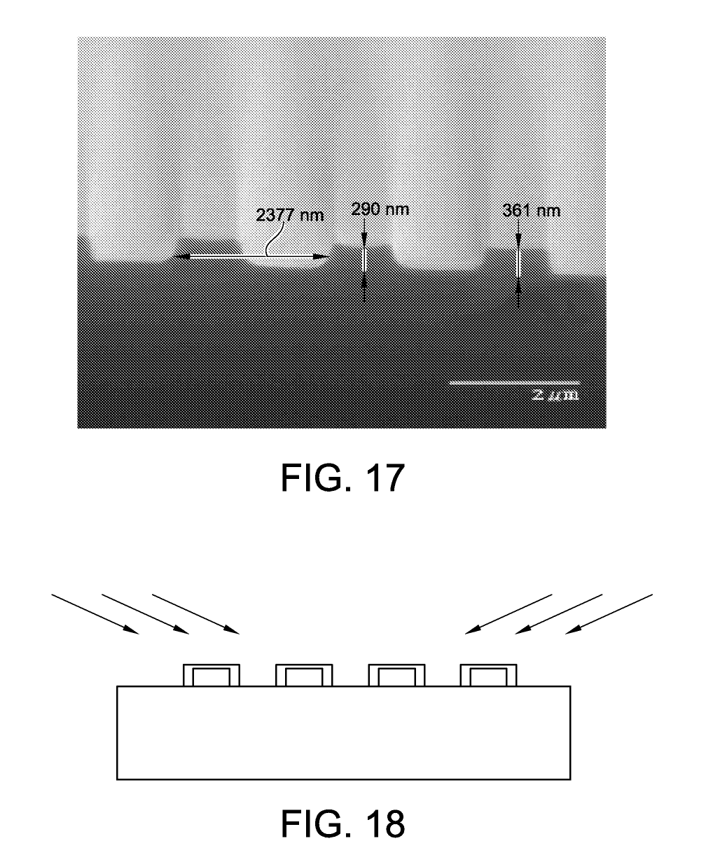

As illustrated in FIG. 17, an alternative embodiment of the present invention utilizes a low aspect ratio structure. This embodiment utilizes the same periodicity as some to the other embodiments, but at a smaller height. In the illustrated embodiment a photoresist master with approximately 2.5 μm periodicity, approximately 1.2 μm width, and approximately 300 nm height was first fabricated on a silicon wafer. PDMS molds were made using the master, and 2P-μTM was used to make one-layer PU grating structures on a glass or sapphire substrates. The scanning electron microscope (SEM) images of the PU grating structure of FIG. 17 show the periodicity is around 2400 nm and the height is around 300 nm. The total area is at 4×4 mm².

In one embodiment as illustrated in FIG. 18, the structure has a higher transmission than that of FIG. 17 with metal deposited on the PU sidewalls. Since the height of the structure is decreased to approximately 300 nm while the width is the same as some previous embodiments at approximately 1.2 μm, the aspect ratio of the PU bars is also changed from 1:1 to 1:4. If the angle of the metal evaporation were still kept at 45° as discussed above, the channels between adjacent PU bars would be coated with metal. This would greatly reduce the optical transmission since the additional metal coating in the channels could block additional light transmitted through the structure. As such, in one embodiment when the deposition angle was approximately 14° with respect to the sample surface, the metal was deposited only on the sidewalls and top of the PU bars as shown in FIG. 18. The samples were then ion milled after the metal deposition as discussed above.

All references, including publications, patent applications, and patents cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A nanoscale high-aspect-ratio metallic structure, comprising:
a substrate transparent to visible light;
a grating structure of polymeric bars attached to the substrate; and
a plurality of metal rails, each metal rail attached to a side wall of the polymeric bars.

2. The nanoscale high-aspect-ratio metallic structure of claim 1, wherein a polymeric adhesive is used to affix the polymeric bars to the substrate.

3. The nanoscale high-aspect-ratio metallic structure of claim 2, wherein the polymeric adhesive comprises polymethacrylate.

4. The nanoscale high-aspect-ratio metallic structure of claim 1, wherein the substrate is transparent to visible light.

5. The nanoscale high-aspect-ratio metallic structure of claim 4, wherein the substrate is glass.

6. The nanoscale high-aspect-ratio metallic structure of claim 4, wherein the substrate is sapphire.

7. The nanoscale high-aspect-ratio metallic structure of claim 1, wherein the polymeric bars are polyurethane bars.

8. The nanoscale high-aspect-ratio metallic structure of claim 1, wherein the metal rails are made from one of copper, silver and gold.

9. The nanoscale high-aspect-ratio metallic structure of claim 1, wherein the polymeric bar has a trapezoidal cross-section.

10. The nanoscale high-aspect-ratio metallic structure of claim 9, wherein the polymeric bar has a base width between 500 nanometers and 1500 nanometers, and a height above the substrate between 300 nanometers and 1500 nanometers, and a base angle of between 8 degrees and 20 degrees.

11. The nanoscale high-aspect-ratio metallic structure of claim 1, wherein the polymeric bars are evenly spaced and parallel to one another, and wherein the spacing is between 0.75 micrometer and 3 micrometers.

12. The nanoscale high-aspect-ratio metallic structure of claim 1, further comprising metal electrode attached to the substrate outside of the grating structure, the metal electrode being electrically coupled to each of the plurality of metal rails.

13. The nanoscale high-aspect-ratio metallic structure of claim 1, further comprising a first metal electrode attached to the substrate at a first end of the polymeric bars of the grating structure and electrically coupled to a first subset of the plurality of metal rails attached to a first side wall of polymeric bars, a second metal electrode attached to the substrate at a second end of the polymeric bars of the grating structure and electrically coupled to a second subset of the plurality of metal rails attached to a second side wall of polymeric bars, the first metal electrode being electrically isolated from the second subset of the plurality of metal rails and the second metal electrode being electrically isolated from the first subset of the plurality of metal rails, the first subset of the plurality of metal rails and the second subset of the plurality of metal rails forming interdigitated electrodes.

14. The nanoscale high-aspect-ratio metallic structure of claim 13, further comprising a material responsive to an electric field positioned between the polymeric bars of the grating structure between the interdigitated electrodes.

15. The nanoscale high-aspect-ratio metallic structure of claim 1, further comprising:
a polyurethane layer encapsulating the grating structure of polymeric bars and the plurality of metal rails; and
a second substrate transparent to light attached to the polyurethane layer.

16. The nanoscale high-aspect-ratio metallic structure of claim 15, wherein the grating structure of polymeric bars includes an underlayer of polyurethane attached to the substrate.

17. The nanoscale high-aspect-ratio metallic structure of claim 1, further comprising:
a polyurethane layer filling the grating structure of polymeric bars between the plurality of metal rails; and
a solar cell electrically coupled to an edge of the plurality of metal rails opposite the substrate.

18. The nanoscale high-aspect-ratio metallic structure of claim 1, further comprising:
a dielectric layer attached to each of the plurality of metal rails; and
a metal layer attached to each of the dielectric layers on each of the metal rails; and
wherein each metal rail, dielectric layer, metal layer for a sandwiched structure.

19. The nanoscale high-aspect-ratio metallic structure of claim 18, wherein the sandwiched structure is attached to only one sidewall of each polymeric bar.

20. The nanoscale high-aspect-ratio metallic structure of claim 1, further comprising:
a second plurality of metal rails, each metal rail of the second plurality of metal rails attached to a second side wall of the polymeric bars; and
an electrically responsive material filling the grating structure of polymeric bars between the plurality of metal rails and the second plurality of metal rails.

21. The nanoscale high-aspect-ratio metallic structure of claim 20, further comprising a second substrate transparent to visible light attached to the polymeric bars.

22. The nanoscale high-aspect-ratio metallic structure of claim 1,
wherein the substrate transparent to visible light has a first side and a second side;
wherein the grating structure of polymeric bars includes a first grating structure of polymeric bars attached to the first side of the substrate, and a second grating structure of polymeric bars attached to the second side of the substrate.

23. The nanoscale high-aspect-ratio metallic structure of claim 22, wherein the first grating structure and the second grating structure are oriented approximately orthogonal to one another.

24. The nanoscale high-aspect-ratio metallic structure of claim 1, further comprising:
a second grating structure of polymeric bars attached and oriented orthogonal to the grating structure that is attached to the substrate; and
a second plurality of metal rails, each of the second plurality of metal rails being attached to a side wall of the second plurality of polymeric bars.

25. A method of fabricating a nanoscale high-aspect-ratio metallic structure, comprising the steps of:
forming a grating structure of polymeric bars by a two-polymer microtransfer molding (2-P μTM) process;
affixing the grating structure of polymeric bars to a transparent substrate;
depositing a metal on a side wall and on a top surface of the polymeric bars; and
removing the metal from the top surface of the polymeric bars.

26. The method of claim 25, wherein the step of depositing the metal comprises the step of angle depositing at an angle relative to the substrate such that metal is not deposited on the substrate between the polymeric bars in the grating structure.

27. The method of claim 26, wherein the step of angle depositing at an angle relative to the substrate such that metal is not deposited on the substrate between the polymeric bars in the grating structure comprises the step of thermal evaporation of the metal at an angle between approximately 14 degrees and 60 degrees relative to a plane of the substrate.

28. The method of claim 25, wherein the step of removing the metal from the top surface of the polymeric bars comprises the step of using one of argon ion milling, reactive ion etching, argon plasma sputtering, and oxygen plasma etching to remove the metal from the top surface of the polymeric bars.

29. The method of claim 25, wherein the step of depositing the metal on each side wall and on the top surface of the polymeric bars includes the step of depositing the metal on the substrate outside of the grating structure to form a metal electrode, the metal electrode being electrically coupled to the metal deposited on each side wall of the polymeric bars.

30. The method of claim 25, wherein the step of depositing the metal on each side wall and on the top surface of the polymeric bars comprises the steps of:
masking a first end portion of the polymeric bars and a first adjacent substrate;
performing a first angle deposition to deposit metal on a first side wall of the polymeric bars not covered by the step of masking and on the substrate outside of the grating structure not covered by the step of masking;
unmasking the first end portion of the polymeric bars and the first adjacent substrate;
masking a second end portion of the polymeric bars and a second adjacent substrate;
performing a second angle deposition to deposit metal on a second side wall of the polymeric bars not covered by the step of masking the second end portion and the substrate outside of the grating structure not covered by the step of masking the second end portion; and
unmasking the second end portion of the polymeric bars and the adjacent substrate.

31. The method of claim 30, wherein the step of removing the metal from the top surface of the polymeric bars includes the step of eliminating an electrical connection between the metal on the first side wall of the polymeric bars and the metal on the second side wall of the polymeric bars thereby forming interdigitated electrodes.

32. The method of claim 31, further comprising the step of filling a volume between the interdigitated electrodes with a material responsive to an electric field.

33. The method of claim 25, further comprising the steps of:
encapsulating the grating structure and the metal layer with a polyurethane layer; and
affixing a second substrate transparent to light to the polyurethane layer.

34. The method of claim 33, wherein the step of forming the grating structure of polymeric bars further comprises the step of forming a grating structure of polymeric bars that includes an underlayer of polyurethane.

35. The method of claim 25, further comprising the steps of:
forming a water-soluble sacrificial layer between the grating structure of polymeric bars and the substrate;
filling the grating structure of polymeric bars with a polyurethane layer;
attaching a second substrate transparent to visible light to the polyurethane layer;
dissolving the water-soluble sacrificial layer;
removing the transparent substrate; and
coupling a solar cell to an exposed edge of the metal.

36. The method of claim 25, wherein the step of depositing the metal on the side wall and on the top surface of the polymeric bars comprising the steps of:
depositing a first metal layer;
depositing a dielectric layer on the first metal layer; and
depositing a second metal layer on the dielectric layer; and
wherein the step of removing the metal from the top surface of the polymeric bars comprises the step of removing the first metal layer, the dielectric layer, and the second metal layer from the top surface of the polymeric bars.

37. The method of claim 25 wherein the step of depositing the metal on the side wall and on the top surface of the polymeric bars comprising the steps of:
depositing a first metal layer on a first side wall and on the top surface of the polymeric bars;
depositing a second metal layer on a second side wall and on the first metal layer on the top surface of the polymeric bars; and
wherein the step of removing the metal from the top surface of the polymeric bars comprises the step of removing the first metal layer and the second metal layer from the top surface of the polymeric bars.

38. The method of claim 37, further comprising the step of filling the grating structure between the polymeric bars with an electrically responsive material.

39. The method of claim 38, further comprising the step of attaching a second transparent substrate to the polymeric bars to form a smart window.
